(19) United States
(12) Patent Application Publication
(10) Pub. No.: US 2010/0073860 A1
(43) Pub. Date: Mar. 25, 2010

(54) SSD APPARATUS

(76) Inventors: Takakatsu MORIAI, Yokohama-shi (JP); Toyokazu Eguchi, Inagi-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/552,546

(22) Filed: Sep. 2, 2009

(30) Foreign Application Priority Data
Sep. 24, 2008 (JP) 2008-244811

(51) Int. Cl. H05K 7/00

(52) U.S. Cl. 361/679.32; 361/679.33

(57) ABSTRACT

A SSD apparatus includes a first memory module, a second memory module, a module controller which determines a method of controlling the first and second memory modules, a control board mounted with the module controller, a first connector which a module board of the first memory module and the control board are connected to, a second connector which a module board of the second memory module and the control board are connected to, and an interface device connected to the control board. A memory chip and a memory controller are mounted on one surface of the module board of each of the first and second memory modules. The other surface of the module board of the first memory module is faced to the other surface of the module board of the second memory module.

### CROSS-REFERENCE TO RELATED APPLICATIONS

This application is based upon and claims the benefit of priority from prior Japanese Patent Application No. 2008-244811, filed Sep. 24, 2008, the entire contents of which are incorporated herein by reference.

### BACKGROUND OF THE INVENTION

1. Field of the Invention

The present invention relates to solid-state disk (SSD) device.

2. Description of the Related Art

A SSD apparatus is a large-capacity data storage device using a nonvolatile semiconductor memory such as a NAND flash memory. The SSD apparatus has an interface which is the same as a magnetic recording hard disk drive (HDD), and therefore recently has come into use in, for example, a personal computer and a server by virtue of increase in the capacity and price reduction.

A method for expansive utilization of HDDs includes a Redundant Arrays of Inexpensive Disks (RAID) method (for example, see Jpn. Pat. Appln. KOKAI Publications Nos. 8-203297 and 10-284684).

A main purpose of the RAID is to build an HDD system with a large capacity or a high reliability with use of small capacity hard disks or hard disks with general reliability. Namely, the RAID is effective to realize the HDD system with a large capacity or a high reliability at low cost.

The RAID has seven types of levels: RAID 0 to RAID 6, and the level is set by, for example, a RAID controller or software.

It is very effective also for the SSD apparatus to apply the RAID method. Namely, the SSD apparatus is smaller in capacity than the HDD device, and therefore, if the capacity of the SSD apparatus is rendered larger by the RAID, the SSD apparatus can approach the HDD device.

For example, at present, while the capacity of the HDD device with a casing size of 2.5 inches is 500 gigabytes, the capacity of the SSD apparatus with the same size is 128 gigabytes.

Thus, according to the RAID method, an SSD system with a combination of two SSD apparatuses is built, whereby the SSD system has a capacity of 256 gigabytes. Meanwhile, the SSD system with a combination of four SSD apparatuses is built, whereby the SSD system has a capacity of 512 gigabytes, and therefore, the SSD apparatus can approach the HDD device.

However, the above argument presupposes that the SSD apparatus is applied to a large product with enough internal space, such as a desktop personal computer (PC). When the SSD apparatus is applied to a small product without enough internal space, such as a notebook PC, SSD apparatuses are basically hardly mounted in the product.

### BRIEF SUMMARY OF THE INVENTION

A SSD apparatus according to an aspect of the present invention comprises a first memory module including a first memory chip, a first memory controller which controls the first memory chip, and a first module board having first and second surfaces, wherein the first memory chip and the first memory controller are mounted on the first surface of the first module board; a second memory module including a second memory chip, a second memory controller which controls the second memory chip, and a second module board having first and second surfaces, wherein the second memory chip and the second memory controller are mounted on the first surface of the second module board, and the second surface of the second module board is faced to the second surface of the first module board; a module controller which determines a method of controlling the first and second memory modules; a control board mounted with the module controller; a first connector which the first module board and the control board are connected to; a second connector which the second module board and the control board are connected to; and an interface device connected to the control board.

### BRIEF DESCRIPTION OF THE SEVERAL VIEWS OF THE DRAWING

FIG. 1 is a view showing an example of a RAID system;

FIG. 2 is a view showing a first proposal for building the RAID system in one SSD apparatus;

FIG. 3 is a view showing a second proposal for building the RAID system in one SSD apparatus;

FIG. 4 is a view showing a third proposal for building the RAID system in one SSD apparatus;

FIG. 5 is an exploded view of the SSD apparatus;

FIGS. 6 and 7 are views, each showing a layout of components in the SSD apparatus;

FIGS. 8 and 9 are views, each showing the SSD apparatus;

FIG. 10 is a circuit diagram showing a power-saving SSD system;

FIG. 11 is a circuit diagram of a power supply controller;

FIG. 12 is an operating waveform chart of the power supply controller of FIG. 11;

FIG. 13 is a circuit diagram of the power supply controller;

FIG. 14 is an operating waveform chart of the power supply controller of FIG. 13;

FIG. 15 is a view showing an example of expanded use of the SSD apparatus; and

FIG. 16 is a view showing a technique for reliability improvement of chips.

### DETAILED DESCRIPTION OF THE INVENTION

An SSD apparatus of an aspect of the present invention will be described below in detail with reference to the accompanying drawings.

### 1. Outline

In an embodiment of the invention, one SSD apparatus includes first and second memory modules and a control board mounted with a module controller, which determines a method of controlling the first and second memory modules, whereby a RAID system is realized in the one SSD apparatus.

The first and second memory modules have a memory chip and a memory controller for controlling the memory chip, which are mounted on one side of a module board. Namely, the first and second memory modules have the same function, and therefore, for example, each memory module can be comprised of an existing unit with guaranteed performance.

Therefore, cost including development cost and material cost newly invested can be reduced, and it is possible to realize a RAID system which is low in cost and, at the same time, in which failure hardly occurs during assembly.

A control board mounted with a module controller determining a method of controlling the first and second memory modules is provided separately from the first and second memory modules. The other sides of the first and second module boards face each other, and the module boards and the control board are connected to each other by a connector.

According to the above structure, signal transmission from the module controller to each memory module can be performed at the same high speed, contributing to realization of high performance.

A power supply chip is further mounted in the first and second memory modules, and the timing at which the power supply of the first memory module rises and the timing at which the power supply of the second memory module rises are made different from each other, whereby a peak value of a so-called surge current generated upon rise of the power supply of the SSD apparatus can be controlled, and therefore, the operational stability can be realized without placing an excessive burden on a power supply device.

In the embodiment of the invention, there is no limitation of the interface of the SSD apparatus.

However, the interface device preferably has at least one slot selected from, for example, Serial Advanced Technology Attachment (SATA), Parallel Advanced Technology Attachment (PATA), Serial Attached Small Computer System Interface (SAS), and Universal Serial Bus (USB).

For the control board, components can be mounted on the both sides of the control board. For instance, the module controller is mounted on one side of the control board, and the interface device is mounted on the other side of the control board, whereby all components can be mounted in a standardized casing.

The standardized casing (for example, 1.8- or 2.5-inch size) is used for ease of dealing with the SSD apparatus, and therefore, it is preferable to provide the casing. However, when the SSD apparatus is mounted in a notebook PC, the casing may not be provided. Thus, the casing is not an essential component of the invention.

### 2. Technique of Building RAID System in One SSD Apparatus

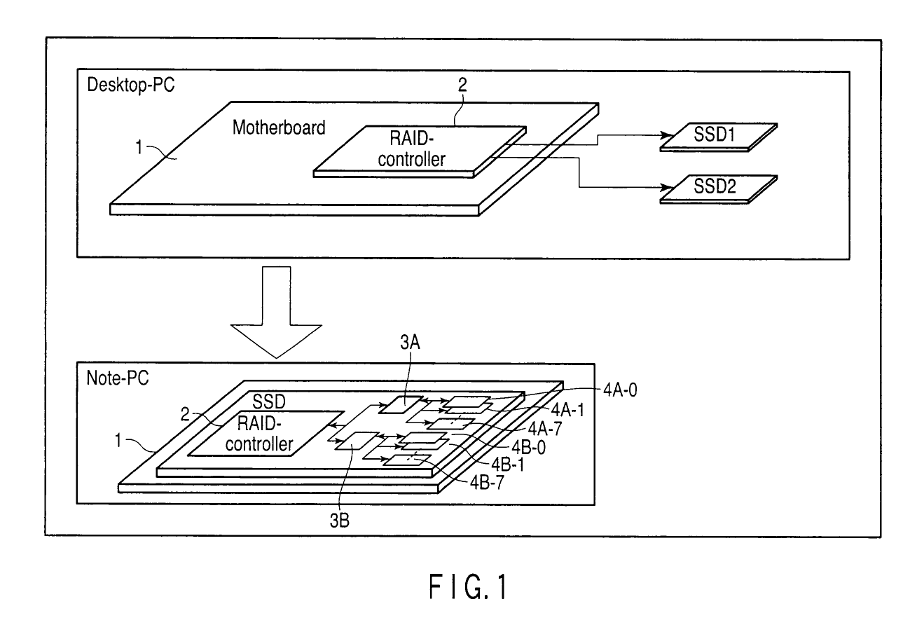

In FIG. 1, a case of building the RAID system in a large product and a case of building the RAID system in a small product are compared with each other.

Since a desktop PC which is a representative of the large product has enough internal space, the desktop PC includes SSD apparatuses (in this embodiment, two SSD apparatuses) SSD1 and SSD2. Thus, SSD apparatuses SSD1 and SSD2 are controlled by RAID-controller (chip) 2 mounted on motherboard 1, whereby the RAID system is built.

Meanwhile, since a notebook PC which is a representative of the small product does not have enough internal space, the notebook PC can include only one SSD apparatus. Thus, the RAID system is required to be built in one SSD apparatus SSD.

In order to build the RAID system in one SSD apparatus SSD, SSD apparatus SSD should include at least a RAID controller (chip) and memory controllers (chips).

For example, there is considered a case in which one memory chip has a capacity of 16 gigabytes, and 8 memory chips are controlled by one memory controller.

In this case, in order to realize a capacity of 256 gigabytes in one SSD apparatus SSD, SSD apparatus SSD should include one RAID controller (one chip) 2, two memory controllers (two chips) 3A and 3B, and 16 memory chips 4A-0 to 4A-7, and 4B-0 to 4B-7.

In addition to the above, for example, a power supply chip is required to be provided.

Thus, in order to build the RAID system in one SSD apparatus SSD, it is important how those chips are laid out.

[First Proposal]

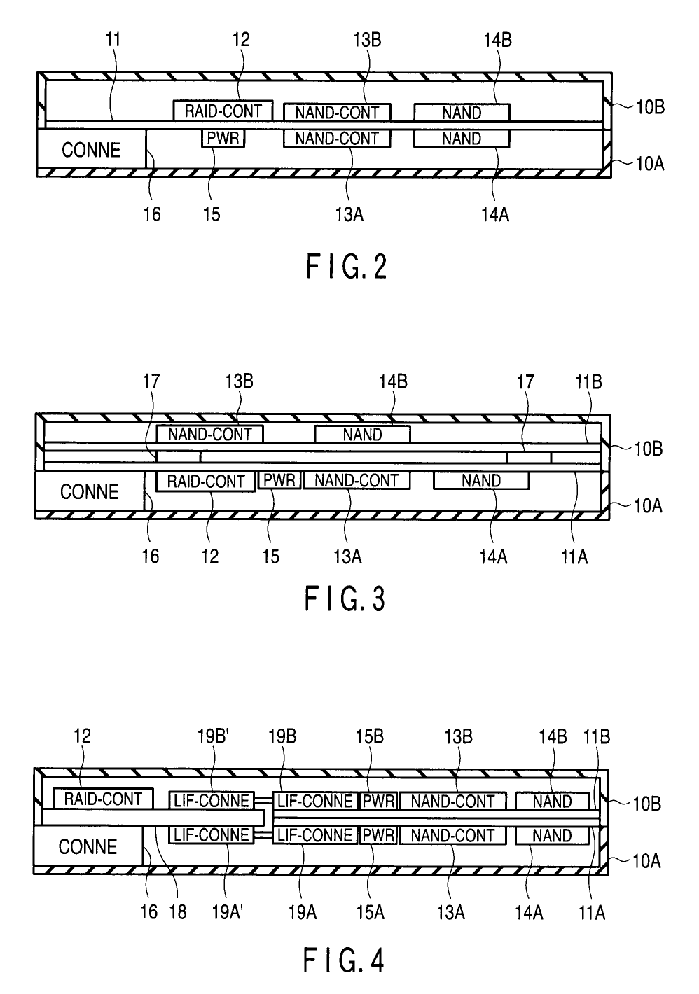

FIG. 2 shows a proposal for using double-sided mounting.

A casing is comprised of bottom cover 10A and top cover 10B.

NAND controller (NAND-CONT) 13A, NAND chip (memory chip) 14A, power supply chip (PWR) 15, and interface device 16 are mounted on one side of printed circuit board 11. RAID controller (RAID-CONT) 12, NAND controller (NAND-CONT) 13B, and NAND chip (memory chip) 14B are mounted on the other side of printed circuit board 11.

The first proposal is characterized in that the both sides of printed circuit board 11 are used as mounting surfaces, on which the chips are mounted, in order to realize the RAID system in a limited space.

In this case, a unit including NAND controller 13A and NAND chip 14A is disposed on one side of printed circuit board 11, and a unit including NAND controller 13B and NAND chip 14B is disposed on the other side of printed circuit board 11.

However, in the double-sided mounting, a reflow (double-sided reflow) process is applied twice to one printed circuit board 11.

For instance, in the first reflow process, NAND controller 13A, NAND chip 14A, and power supply chip 15 are soldered onto one side of printed circuit board 11. In the second reflow process, RAID controller 12, NAND controller 13B, and NAND chip 14B are soldered onto the other side of printed circuit board 11.

According to the first proposal, the RAID system can be built in one SSD apparatus SSD.

[Second Proposal]

FIG. 3 shows a proposal for using a stack method for stacking two printed circuit boards.

The casing is comprised of bottom cover 10A and top cover 10B.

RAID controller (RAID-CONT) 12, NAND controller (NAND-CONT) 13A, NAND chip (memory chip) 14A, power supply chip (PWR) 15, and interface device 16 are mounted on one side of printed circuit board 11A. NAND controller (NAND-CONT) 13B and NAND chip (memory chip) 14B are mounted on one side of printed circuit board 11B.

Thin connector 17 is disposed between printed circuit boards 11A and 11B in a state that the other sides of printed circuit boards 11A and 11B face each other. Although one thin connector 17 is usually used, thin connectors may be used as in this embodiment depending on signal splitting.

The second proposal is characterized in that two printed circuit boards 11A and 11B are stacked to be used in order to solve the problem in the double-sided mounting.

In this case, a unit including RAID controller 12, NAND controller 13A, and NAND chip 14A is disposed on one side of printed circuit board 11A, and a unit including NAND controller 13B and NAND chip 14B is disposed on one side of printed circuit board 11B.

In the second proposal, in comparison with the first proposal, since heat stress is reduced, the reliability of chips can be improved, and, at the same time, a problem due to warpage of the printed circuit board caused by the heat stress will not occur. Further, signal interference hardly occurs, and thus the reliability of the system can be improved.

Also in the second proposal, the RAID system can be built in one SSD apparatus SSD.

[Third Proposal]

FIG. 4 shows a proposal as an improved version of the stack method of the second proposal.

The casing is comprised of bottom cover 10A and top cover 10B.

NAND controller (NAND-CONT) 13A, NAND chip (memory chip) 14A, and power supply chip (PWR) 15A are mounted on one side of printed circuit board (module board) 11A. NAND controller (NAND-CONT) 13B, NAND chip (memory chip) 14B, and power supply chip (PWR) 15B are mounted on one side of printed circuit board (module board) 11B.

The other sides of printed circuit boards 11A and 11B face each other. Here, an insulating sheet may be interposed between printed circuit boards 11A and 11B.

Control board 18 mounted with RAID controller (RAID-CONT) 12 is provided separately from two printed circuit boards 11A and 11B. Printed circuit board 11A and control board 18 are connected to each other by connectors 19A and 19A′. Printed circuit board 11B and control board 18 are connected to each other by connectors 19B and 19B′.

Each of connectors 19A, 19A′, 19B, and 19B′ is comprised of, for example, a flexible printed circuit (FPC) board, a thin rigid board, and a directly connected connector.

The third proposal is characterized in that control board 18 mounted with RAID controller 12 is newly provided separately from two printed circuit boards 11A and 11B in order to solve the problem in the stack method.

In this case, firstly, the layouts of two printed circuit boards 11A and 11B can be made the same. Namely, printed circuit boards 11A and 11B can be used as memory modules having the same function.

Thus, for example, each memory module is comprised of an existing unit with guaranteed performance, whereby a low-cost and highly reliable RAID system can be realized.

Secondly, the other sides of two printed circuit boards (module boards) 11A and 11B face each other, and printed circuit boards 11A and 11B and control board 18 are connected to each other by connectors 19A, 19A′, 19B, and 19B′.

Therefore, a thin connector is not required to be provided between two printed circuit boards 11A and 11B, whereby further cost reduction can be realized. Further, the signal transmission from RAID controller (module controller) 12 to each memory module can be performed at the same high speed, contributing to realization of high performance.

Thirdly, printed circuit boards 11A and 11B are modularized, whereby a power supply chip is mounted in each memory module. By using this structure, the respective timings at which the power supplies of the memory modules rise are made different from each other, whereby the peak value of the surge current generated upon rise of the power supply of the SSD apparatus can be controlled, and therefore, the operational stability can be realized.

Also in the third proposal, the RAID system can be built in one SSD apparatus SSD.

### 3. Embodiment

(1) Overall Configuration

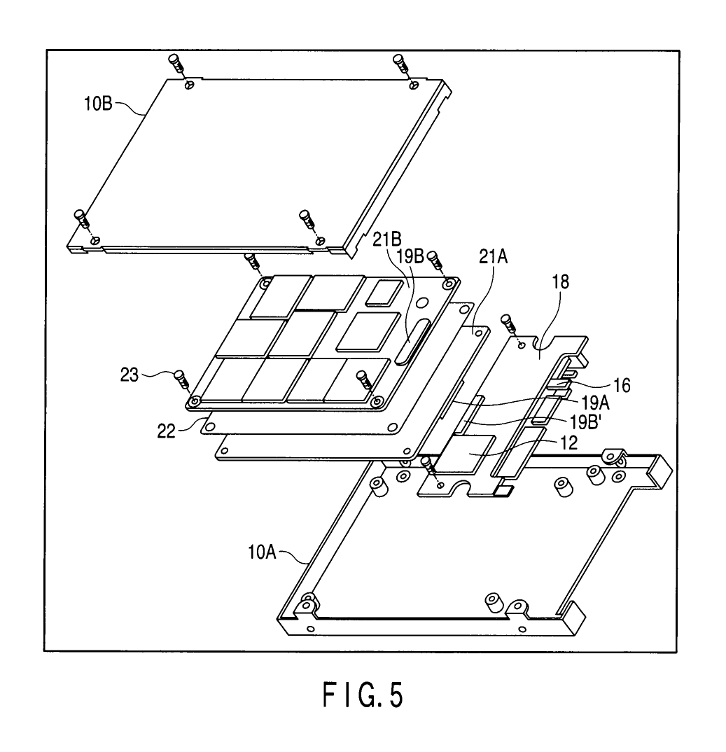

FIG. 5 is an exploded view of an SSD apparatus according to an embodiment of the invention.

The standardized casing (for example, 1.8- or 2.5-inch size) is comprised of bottom cover 10A and top cover 10B.

In order to reduce a newly invested cost including development cost and material cost, existing units with guaranteed performance are used as they are as memory modules 21A and 21B. Namely, the configurations (for example, the components and the layouts) of memory modules 21A and 21B are the same as those of the existing units.

Memory module 21A includes, for example, NAND controller 13A, NAND chip 14A, and power supply chip 15A of FIG. 4. Memory module 21B includes, for example, NAND controller 13B, NAND chip 14B, and power supply chip 15B of FIG. 4.

Memory modules 21A and 21B are in a state that the other sides of the printed circuit boards, on which no chips are mounted, face each other. Insulating sheet 22 is disposed between memory modules 21A and 21B.

RAID controller (module controller) 12, which determines a method of controlling memory modules 21A and 21B, for example RAID 0 to RAID 6, is mounted on control board (RAID control board) 18.

Further, interface device 16, which has a slot corresponding to, for example, SATA, PATA, SAS, and USB, is mounted on control board 18.

Memory module 21A and control board 18 are connected to each other by connectors 19A and 19A′, for example, flexible printed circuit (FPC) connectors. And memory module 21B and control board 18 are connected to each other by connectors 19B and 19B′, for example, FPC connectors.

The printed circuit board in memory modules 21A and 21B and control board 18 are comprised of, for example, an FPC board and a rigid board. Those boards preferably have a multilayer structure.

Memory modules 21A and 21B and control board 18 are sandwiched between bottom cover 10A and top cover 10B to be fixed by fixing parts 23 such as screws, whereby the SSD apparatus is complete.

(2) Layout

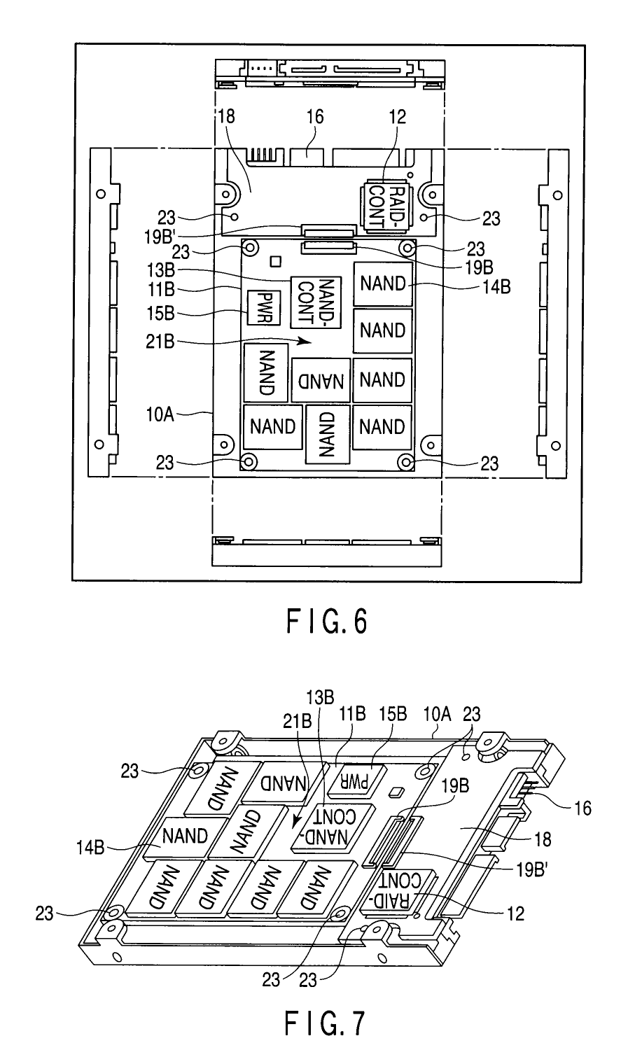

FIGS. 6 and 7 are views showing a layout of components in the SSD apparatus.

FIGS. 6 and 7 show the configuration of the SSD apparatus with a top cover removed therefrom. Memory module 21B is disposed on the top cover side. The memory module disposed on the side of bottom cover 10A is in a state of hiding in memory module 21B and thus not illustrated.

Printed circuit board (module board) 11B of memory module 21B and control board 18 are fixed to bottom cover 10A by fixing parts 23 such as screws. Printed circuit board 11B and control board 18 are arranged with a fixed distance to be connected to each other by connectors 19B and 19B′.

RAID controller 12 is disposed on one side of control board 18 on the top cover side. Interface device 16 is disposed on the other side of control board 18 on the side of bottom cover 10A.

Printed circuit board 11B has on its one side on the top cover side one NAND controller (NAND-CONT) 13B, eight NAND chips (memory chips) 14B, and one power supply chip (PWR) 15B.

NAND controller 13B and power supply chip 15B are disposed near connector 19B for speed-up (reduction of parasitic capacitance and parasitic resistance of signal lines).

In this embodiment, eight NAND chips 14B are disposed along two sides of NAND controller 13B and power supply chip 15B so as to surround NAND controller 13B and power supply chip 15B.

It is preferable that eight NAND chips 14B are laid out so that the difference in the distances from NAND controller 13B and power supply chip 15B to the respective chips is decreased.

The configuration (for example, the components and the layout) of the memory module disposed on the side of bottom cover 11A is the same as that of memory module 21B.

(3) Detail View

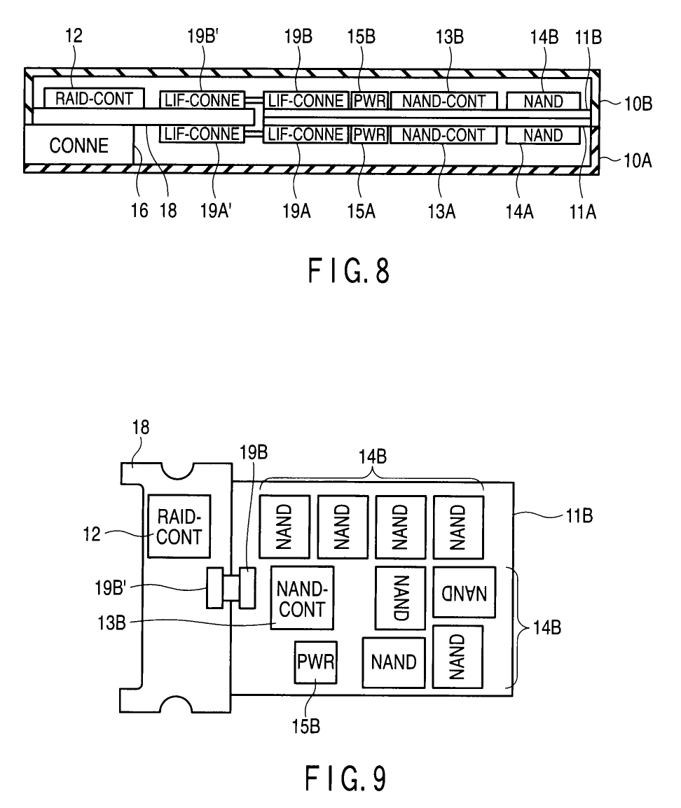

FIG. 8 is a cross-sectional view of the SSD apparatus according to the embodiment of the invention. FIG. 9 is a detail view of the memory modules and the control board of the SSD apparatus according to the embodiment of the invention.

The casing is comprised of bottom cover 10A and top cover 10B. The first and second memory modules and control board 18 according to the invention are disposed in the casing.

The first memory module is comprised of NAND controller (NAND-CONT) 13A, NAND chip (memory chip) 14A, power supply chip (PWR) 15A, and printed circuit board (module board) 11A mounted with them.

The second memory module is comprised of NAND controller (NAND-CONT) 13B, NAND chip (memory chip) 14B, power supply chip (PWR) 15B, and printed circuit board (module board) 11B mounted with them.

RAID controller (RAID-CONT) 12 and interface device 16 are mounted on control board 18.

Printed circuit board 11A and control board 18 are connected to each other by connectors 19A and 19A′. Printed circuit board 11B and control board 18 are connected to each other by connectors 19B and 19B′.

(4) Power-Saving Technology

A power-saving technology, which can be applied to the SSD apparatus according to the embodiment of the invention, is described.

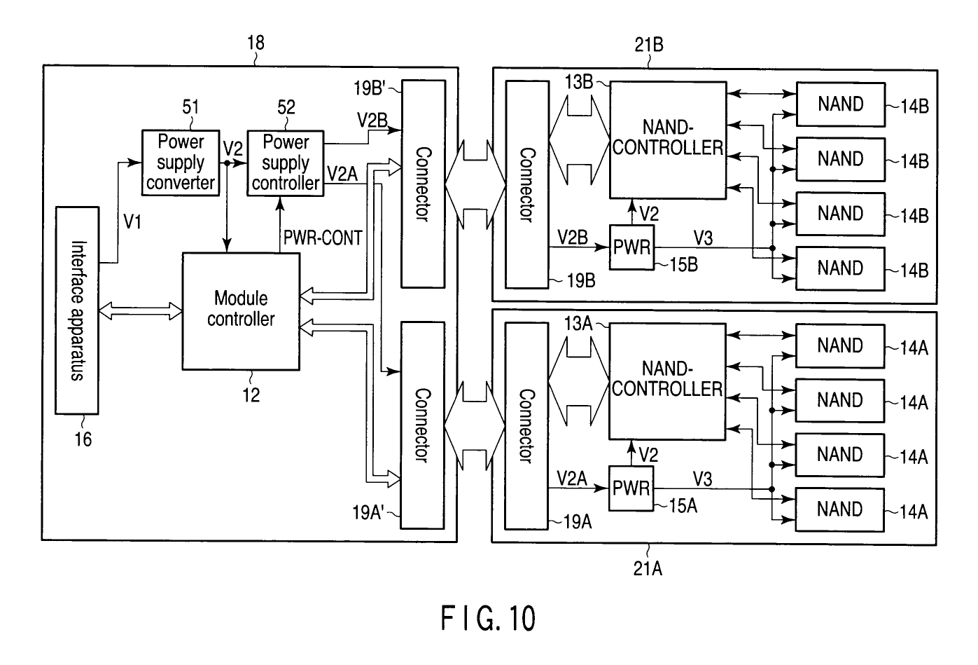

FIG. 10 shows a power-saving SSD system.

The SSD system is characterized in that power supply controller 52 is mounted on control board 18. Power supply controller 52 may be a single chip, or may be contained in one chip along with, for example, a power supply converter.

First memory module 21A, that is, NAND controller (memory controller) 13A, NAND chip (memory chip) 14A, power supply chip 15A, and connectors 19A and 19A′ are the same as in the above embodiment.

Second memory module 21B, that is, NAND controller (memory controller) 13B, NAND chip (memory chip) 14B, power supply chip 15B, and connectors 19B and 19B′ are the same as in the above embodiment.

Power supply potential (for example, 5 V) V1 is input to power supply converter 51 through interface device (for example, SATA interface device) 16.

Power supply converter 51 converts power supply potential V1 into power supply potential (for example, 3.3 V) V2. Power supply potential V2 is supplied to module controller 12, and, at the same time, input to power supply controller 52.

In some interface devices 16, power supply converter 51 may be omitted. For example, when the power supply potential supplied from outside through interface device 16 is V2 (for example, 3.3 V), power supply converter 51 may be omitted.

Power supply controller 52 generates power supply potential V2A, supplied to first memory module 21A, and power supply potential V2B, supplied to second memory module 21B, based on control signal PWR-CONT from module controller 12.

Power supply potential V2A passes through connectors (for example, SATA connectors) 19A and 19A′ to be supplied to power supply chip (PWR) 15A in first memory module 21A. Power supply chip 15A generates power supply potential V2, supplied to NAND controller 13A, and power supply potential V3, supplied to NAND chip 14A, based on power supply potential V2A.

Power supply potential V2B passes through the connectors (for example, SATA connectors) 19B and 19B′ to be supplied to power supply chip (PWR) 15B in second memory module 21B. Power supply chip 15B generates power supply potential V2, supplied to NAND controller 13B, and power supply potential V3, supplied to NAND chip 14B, based on power supply potential V2B.

Power supply controller 52 has a function of shifting the timing at which the power supply potential V2A supplied to first memory module 21A rises from the timing at which power supply potential V2B supplied to second memory module 21B rises.

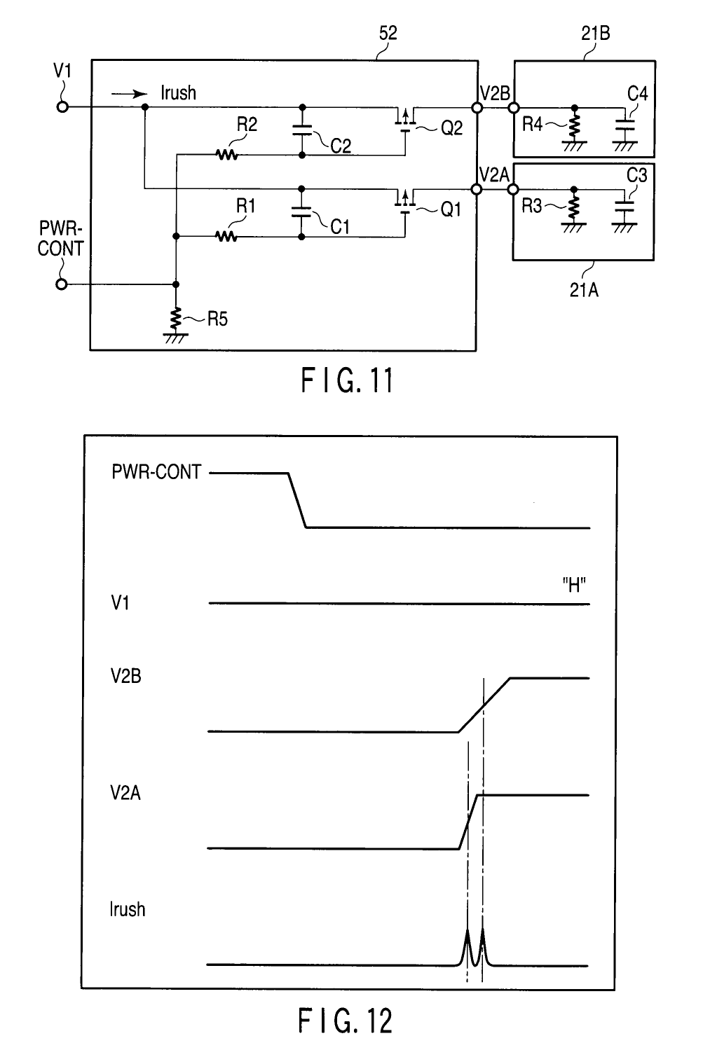

FIG. 11 shows a first circuit example of the power supply controller.

Power supply controller 52 is comprised of resistors R1, R2, and R5, capacitors C1 and C2, and p-channel MOS transistors Q1 and Q2. Resistor R3 and capacitor C3 are equivalent circuits of first memory module 21A. Resistor R4 and capacitor C4 are equivalent circuits of second memory module 21B.

In this embodiment, capacitances of capacitors C1 and C2 are made different from each other, or resistances of resistors R1 and R2 are made different from each other, whereby the timing at which power supply potential V2A rises and the timing at which power supply potential V2B rises can be shifted from each other.

FIG. 12 is an operating waveform chart of the power supply controller of FIG. 11.

The waveform chart shows an example of the case in which, in the circuit diagram of FIG. 11, the capacitance of capacitor C1 is rendered smaller than the capacitance of capacitor C2, and, at the same time, the resistances of resistors R1 and R3 and the capacitance of capacitor C3 are made equal respectively to the resistances of resistors R2 and R4 and the capacitance of capacitor C4.

In a state that power supply potential V1 is high, when control signal PWR-CONT goes low, p-channel MOS transistors Q1 and Q2 are kept on. Therefore, power supply potentials V2A and V2B gradually increase; however, they are different in rise time at this time.

Namely, since the capacitance of capacitor C2 of a circuit on the side of power supply potential V2B is larger than the capacitance of capacitor C1 of a circuit on the side of power supply potential V2A, a time constant of the circuit on the side of power supply potential V2B is larger than a time constant of the circuit on the side of power supply potential V2A.

Thus, the rise timing of power supply potential V2B is later than the rise timing of power supply potential V2A.

According to the above structure, for a peak value of surge current Irush of V1 which is a source of power supply potentials V2A and V2B, in comparison with a case in which the rising waveforms of power supply potentials V2A and V2B are the same (the peak value of the surge current is twice the peak value of the surge current attributable to the rise of power supply potential V2A), the peak value of the surge current Irush of V1 is reduced by shifting of the timing of the peak generation.

The rise time of power supply potential V2B (for example, about 10 ms) is longer than the rise time of power supply potential V2A (for example, about 2 to 3 ms), whereby the amount of surge current Irush attributable to the rise of power supply potential V2B is reduced, thus contributing to low power consumption.

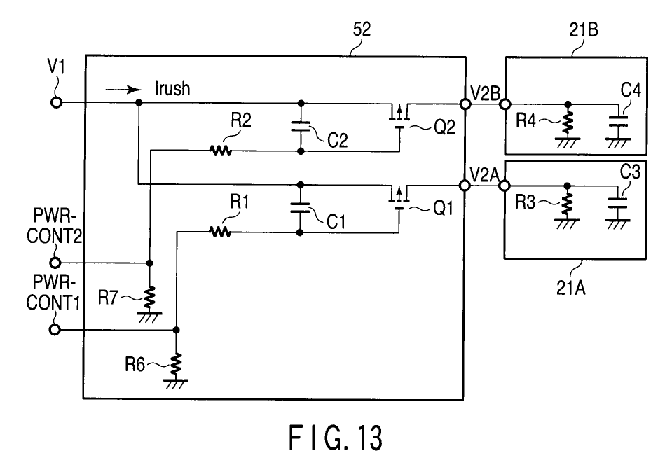

FIG. 13 shows a second circuit example of the power supply controller.

Power supply controller 52 is comprised of resistors R1, R2, R6, R7, capacitors C1 and C2, and p-channel MOS transistors Q1 and Q2. Resistor R3 and capacitor C3 are equivalent circuits of first memory module 21A. Resistor R4 and capacitor C4 are equivalent circuits of second memory module 21B.

In this embodiment, the capacitances of capacitors C1 and C2 are made different from each other, or the resistances of resistors R1 and R2 are made different from each other, whereby the rise timing of power supply potential V2A and the rise timing of power supply potential V2B can be shifted from each other.

In the first circuit example, a circuit for generating power supply potential V2A and a circuit for generating power supply potential V2B are enabled by control signal PWR-CONT. Meanwhile, in the second circuit example, a circuit for generating power supply potential V2A is enabled by control signal PWR-CONT1, and a circuit for generating power supply potential V2B is enabled by control signal PWR-CONT2.

In this embodiment, timings of asserting two control signals PWR-CONT1 and PWR-CONT2 are made different from each other, whereby the rise timing of power supply potential V2A and the rise timing of power supply potential V2B can be shifted with respect to power supply potential V1.

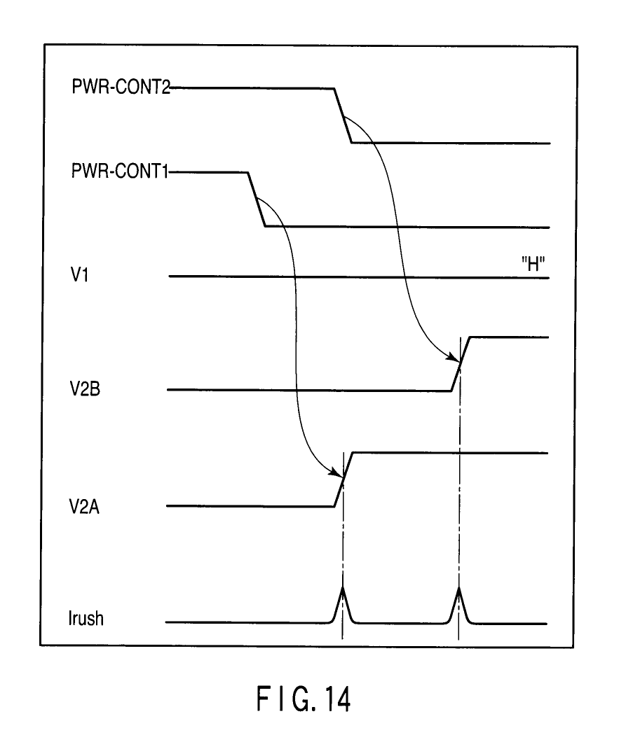

FIG. 14 is an operating waveform chart of the power supply controller of FIG. 13.

The waveform chart shows an example of the case in which, in the circuit diagram of FIG. 13, the timing of asserting control signal PWR-CONT1 is rendered earlier than the timing of asserting control signal PWR-CONT2, and, at the same time, the resistances of resistors R1 and R3 and the capacitances of capacitors C1 and C3 are rendered equal respectively to the resistances of resistors R2 and R4 and the capacitances of capacitors C2 and C4.

In a state that power supply potential V1 is high, control signal PWR-CONT1 is first asserted. Namely, control signal PWR-CONT1 is made low. Then, p-channel MOS transistor Q1 is kept on.

According to the above structure, power supply potential V2A gradually increases. At this time, surge current Irush with a constant magnitude is generated.

The peak value of surge current Irush attributable to the rise of power supply potential V2A depends on the time constant determined by the resistances of resistors R1 and R3 and the capacitances of capacitors C1 and C3.

Next, control signal PWR-CONT2 is asserted. Namely, control signal PWR-CONT2 is made low. Then, p-channel MOS transistor Q2 is kept on.

According to the above structure, power supply potential V2B gradually increases. Also at this time, surge current Irush with a constant magnitude is generated.

The peak value of surge current Irush attributable to the rise of power supply potential V2B depends on the time constant determined by the resistances of resistors R2 and R4 and the capacitances of capacitors C2 and C4.

Thus, in comparison with a case in which the rising waveforms of power supply potentials V2A and V2B are the same (the peak value of surge current Irush of V1, which is a source of power supply potentials V2A and V2B, is twice the peak value of surge current Irush attributable to the rise of power supply potentials V2A and V2B), the peak value of surge current Irush of V1 is reduced by shifting of the timing of peak generation.

### 4. Application Example

According to the SSD apparatus according to the embodiment of the invention, since the control board mounted with the RAID controller is provided separately from the printed circuit board (module board), the first and second memory modules can be comprised of an existing unit with guaranteed performance.

Therefore, the RAID system can be easily built in one SSD apparatus, and, at the same time, the SSD apparatus is not required to be redesigned from the beginning, whereby a high-quality finished product can be provided.

Further, since a design resource can be reduced, the development within a short delivery period of time can be realized. Furthermore, a conventional technique of the SSD apparatus can be diverted, and therefore, in terms of performance to cost, a high-performance product can be provided.

Furthermore, no restrictions are imposed on the interface, whereby the range of application of the SSD apparatus can be enlarged.

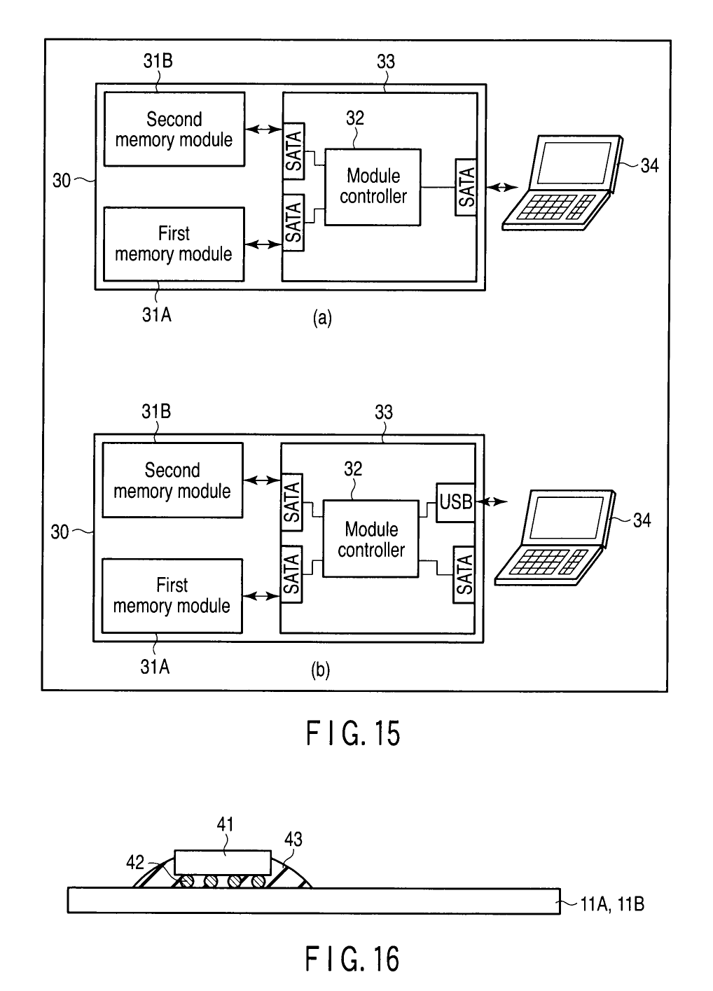

For example, FIG. 15 shows an example of enlarging the range of application of the SSD apparatus.

Reference numerals 30, 31A, 31B, 32, 33, and 34 respectively denote an SSD apparatus, a first memory module, a second memory module, a module controller, a control board, and notebook PC.

In FIG. 15A, the interface of SSD apparatus 30 corresponds to SATA. In this case, SSD apparatus 30 can fulfill its original function as a secondary storage memory of the notebook PC 34.

In FIG. 15B, the interface of SSD apparatus 30 corresponds to SATA and USB. In this case, SSD apparatus 30 can be used as a USB memory by enabling the interface of USB.

However, module controller 32 is required to handle two interfaces of SATA and USB.

Since the design of the control board has a degree of freedom, the control board can be designed in consideration of the assembling of the SSD apparatus.

Further, the following technique can be applied to the chips in the first and second memory modules for reliability improvement.

For example, FIG. 16 shows an example of a technique for the reliability improvement.

In this example, in the reflow process, chip (for example, a NAND controller, a NAND chip, or a power supply chip) 41 is mounted on printed circuit boards 11A and 11B, and thereafter, resin 43 is supplied in between bumps (solder) 42 to harden. According to this structure, the connection between printed circuit boards 11A and 11B and chip 41 is strengthened, and, at the same time, bumps 42 can be protected from breaking and corrosion.

Further, the signal transmission from RAID controller (module controller) 12 to the first and second memory modules can be performed at the same high speed, contributing to realization of high performance.

Furthermore, the rise timing of the power supply of the first memory module and the rise timing of the power supply of the second memory module are made different from each other, whereby the peak value of the surge current generated upon rise of the power supply of the SSD apparatus can be controlled, thus contributing to the power saving.

### 5. Others

The SSD apparatus according to the embodiment of the invention is effective when the semiconductor memory is a NAND flash memory; however, the semiconductor memory is not limited to the NAND flash memory. Namely, the memory module according to the embodiment of the invention may have memory chips as a nonvolatile semiconductor memory and a memory controller for controlling them.

Such a nonvolatile semiconductor memory would be resistive RAM (ReRAM), magnetic RAM (MRAM), phase-change RAM (PRAM), and ferromagnetic RAM (FeRAM).

The module controller determining a method of controlling memory modules is not limited to the RAID controller following the RAID method.

### 6. Conclusion

According to the invention, the RAID system can be built in one SSD apparatus.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A SSD apparatus comprising:
a first memory module including:
a first memory chip;
a first memory controller which controls the first memory chip; and
a first module board having first and second surfaces, wherein the first memory chip and the first memory controller are mounted on the first surface of the first module board;
a second memory module including:
a second memory chip;
a second memory controller which controls the second memory chip; and
a second module board having first and second surfaces, wherein the second memory chip and the second memory controller are mounted on the first surface of the second module board, and the second surface of the second module board is faced to the second surface of the first module board;
a module controller which determines a method of controlling the first and second memory modules;
a control board mounted with the module controller;
a first connector which the first module board and the control board are connected to;
a second connector which the second module board and the control board are connected to; and
an interface device connected to the control board.

2. The apparatus according to claim 1,
wherein the first memory module, the second memory module, the module controller, the control board, the first connector, the second connector and the interface device are provided in a casing.

3. The apparatus according to claim 1,
wherein the interface device has at least one slot selected from SATA, PATA, SAS and USB.

4. The apparatus according to claim 1,
wherein the control board has first and second surfaces, the module controller is mounted on the first surface of the control board, and the interface device is mounted on the second surface of the control board.

5. The apparatus according to claim 1,
wherein the rise timing of a power supply potential of the first memory module is different from the rise timing of a power supply potential of the second memory module.

6. The apparatus according to claim 1,
wherein the method of controlling the first and second memory modules is a RAID method.

7. The apparatus according to claim 1,
wherein the casing is a standardized casing.

8. The apparatus according to claim 1,
wherein the casing is comprised of a bottom cover and a top cover.

9. The apparatus according to claim 1,
wherein each of the first and second module board is a printed circuit board.

10. The apparatus according to claim 1, further comprising
an insulating sheet between the second surface of the first module board and the second surface of the second module board.

11. The apparatus according to claim 1,
wherein each of the first and second connector is one of a flexible printed circuit board, a thin rigid board and a directly connected connector.

12. The apparatus according to claim 1,
wherein layouts of the first and second module boards are the same.

13. The apparatus according to claim 1,
wherein the first and second module boards has the same function.

14. The apparatus according to claim 1,
wherein the first memory controller is nearer to the first connector than the first memory chip.

15. The apparatus according to claim 1,
wherein the second memory controller is nearer to the second connector than the second memory chip.

16. The apparatus according to claim 5, further comprising
a power supply controller mounted on the control board, which controls the rise timing of each of the power supply potentials of the first and second memory modules.

17. The apparatus according to claim 16,
wherein the power supply controller includes a resistor, a capacitor and a MOS transistor.

18. The apparatus according to claim 1,
wherein the apparatus is mounted in a notebook PC.

19. The apparatus according to claim 1,
wherein each of the first and second memory chips is a NAND flash memory.

20. The apparatus according to claim 1, further comprising
a first power supply chip mounted on the first surface of the first module board, and a second power supply chip mounted on the first surface of the second module board, wherein each of the first and second power supply chips has bumps protected by a resin.
